(19) United States
(12) Patent Application Publication
(10) Pub. No.: US 2026/0290489 A1
(43) Pub. Date: Sep. 24, 2026

(54) MEMORY SPARING USING ROW REMAPPING AND APPLICATION-SPECIFIC INTEGRATED CIRCUIT RESOURCES

(71) Applicant: Micron Technology, Inc., Boise, ID (US)

(72) Inventors: Daniele Balluchi, Cernusco Sul Naviglio (MI) (IT); Su Wei Lim, Penang (MY); Marco Sforzin, Cernusco Sul Naviglio (MI) (IT); Graziano Mirichigni, Vimercate (MB) (IT); Rishabh Dubey, Agrate Brianza (MB) (IT)

(21) Appl. No.: 19/557,824

(22) Filed: Mar. 5, 2026

Related U.S. Application Data
(60) Provisional application No. 63/773,988, filed on Mar. 18, 2025.

(51) Int. Cl. G11C 29/00; G11C 11/4096; G11C 29/52

(52) U.S. Cl. CPC G11C 29/76; G11C 11/4096; G11C 29/52

(57) ABSTRACT

Methods, systems, and devices for memory sparing using row remapping and application-specific integrated circuit resources are described. A memory system may perform memory repair and recovery using additional resources at a memory system controller, using additional spare resources within the memory according to data compression, or both. A memory system controller may include one or more buffers that include volatile resources allocated for memory sparing. During a write operation, if the data is to be written to a failed region of memory, the memory system controller may write the data to a buffer at the controller and may remap the target address to the buffer. Additionally, or alternatively, extra rows, columns, and chunks of memory that are available after data compression may be repurposed for memory sparing. The memory system may remap addresses of failed rows, chunks, or columns of memory to the extra rows, columns, and chunks of memory.

### CROSS REFERENCE

The present Application for Patent claims priority to U.S. Patent Application No. 63/773,988 by Balluchi et al., entitled “MEMORY SPARING USING ROW REMAPPING AND APPLICATION-SPECIFIC INTEGRATED CIRCUIT RESOURCES,” filed Mar. 18, 2025, which is assigned to the assignee hereof, and which is expressly incorporated by reference in its entirety herein.

### TECHNICAL FIELD

The following relates to one or more systems for memory, including memory sparing using row remapping and application-specific integrated circuit resources.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports memory sparing using row remapping and application-specific integrated circuit resources in accordance with examples as disclosed herein.

FIG. 2 shows example architecture that supports memory sparing using row remapping and application-specific integrated circuit resources in accordance with examples as disclosed herein.

FIG. 3 shows example architecture that supports memory sparing using row remapping and application-specific integrated circuit resources in accordance with examples as disclosed herein.

FIGS. 4A and 4B show examples of encoding schemes that support memory sparing using row remapping and application-specific integrated circuit resources in accordance with examples as disclosed herein.

FIG. 5 shows example architecture that supports memory sparing using row remapping and application-specific integrated circuit resources in accordance with examples as disclosed herein.

FIG. 6 shows example architecture that supports memory sparing using row remapping and application-specific integrated circuit resources in accordance with examples as disclosed herein.

FIG. 7 shows an example of an encoding scheme that supports memory sparing using row remapping and application-specific integrated circuit resources in accordance with examples as disclosed herein.

FIG. 8 shows a block diagram of a memory system that supports memory sparing using row remapping and application-specific integrated circuit resources in accordance with examples as disclosed herein.

FIGS. 9 and 10 show flowcharts illustrating a method or methods that support memory sparing using row remapping and application-specific integrated circuit resources in accordance with examples as disclosed herein.

### DETAILED DESCRIPTION

Some memory systems may support error detection and correction techniques. For example, the memory system may detect errors when accessing memory, and may correct the errors in one or more regions of memory. The error correction scheme may be a single die data correction (SDDC) scheme or a double die data correction (DDDC) scheme, among other examples. In some examples, the memory system may support memory sparing, which may include replacing one or more unreliable physical memory regions (e.g., rows, columns, portions of rows or columns) within the memory system with one or more spare memory resources. The memory system may include one or more spare resources (e.g., rows, columns, portions of rows or columns) available per bank or on some other granularity of spare resources available for memory sparing. The memory sparing may be part of a post package repair (PPR) technique in some cases. However, some memory systems may experience multiple failures per bank or some other quantity of increased errors in memory, such that the spare resources (such as for PPR) may not be sufficient to repair and replace the failed memory regions.

As described herein, the memory system may perform further memory repair and recovery using additional resources at a memory system controller, using additional spare resources within the memory according to data compression, or both. For example, a memory system controller (e.g., an application specific integrated circuit (ASIC)) associated with interfacing between the memory system and a host system in accordance with a communication or memory access protocol (e.g., compute express link (CXL)) may include one or more buffers (e.g., memory sparing buffers) that include volatile resources allocated for memory sparing. During a write operation, the memory system controller may determine whether the data to be written is targeting a failed region of memory. A failed region of memory may refer to a row, a column, or a chunk that is undergoing repair (e.g., designated for repair, is considered as repaired according to the memory sparing techniques described herein). Additionally, or alternatively, a failed region of memory may refer to a region of memory that is no longer reliable. A chunk as described herein may refer to a portion of a row or a portion of a column. If the data is to be written to a failed region of memory, the memory system controller may write the data to a buffer at the controller and may remap the target address to the buffer. When the data is requested (for example, to be read), the memory system controller may overwrite data read from the memory region with the data pulled from the buffer. As such, the resources at the memory system controller may be used to expand memory sparing capabilities even if spare resources in the system have been depleted. Additionally, or alternatively, the memory system controller may compress data received from a host system before writing the data to the memory devices. For example, a controller (e.g., a CXL controller or other type of controller) may perform data compression according to a data compression rate. The compression may increase available resources in the memory system. As such, extra rows, columns, or chunks that are available after data compression may be repurposed for memory sparing. The memory system may remap addresses of failed rows, columns, or chunks of memory to the extra rows, columns, and chunks of memory during access operations to extend a lifetime of the system and improve reliability and performance, among other examples.

In addition to applicability in memory systems as described herein, techniques for memory sparing using row remapping and application-specific integrated circuit resources may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by extending a lifetime of memory systems and reducing materials and cost associated with productions of such systems, which may result in lowered production emissions and reduced electronic waste, among other benefits.

Features of the disclosure are illustrated and described in the context of systems and architectures. Features of the disclosure are further illustrated and described in the context of architectures, encoding schemes, block diagrams, and flowcharts.

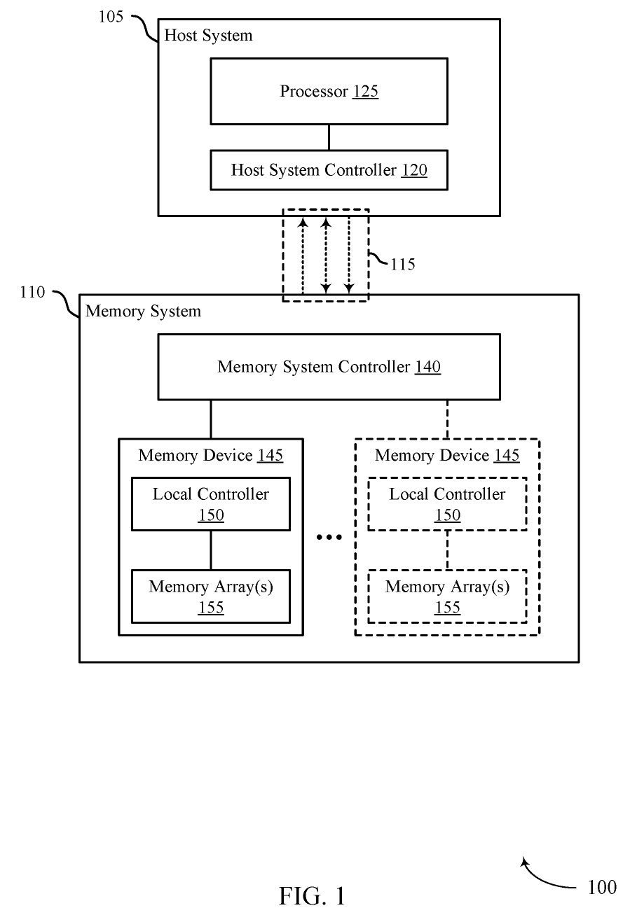

FIG. 1 shows an example of a system 100 that supports memory sparing using row remapping and application-specific integrated circuit resources in accordance with examples as disclosed herein. The system 100 may include portions of an electronic device, such as a computing device, a mobile computing device, a wireless communications device, a graphics processing device, a server, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

Signaling may be communicated over the channels 115 using single data rate (SDR) signaling or double data rate (DDR) signaling, among other rates (e.g., relative to a clock signal). In SDR signaling, one modulation symbol (e.g., signal level) of a signal may be registered for each clock cycle (e.g., on a rising edge or a falling edge of a clock signal). In DDR signaling, two modulation symbols of a signal may be registered for each clock cycle (e.g., on both a rising edge and a falling edge of a clock signal).

The memory system 110 may implement or may be an example of a compute express link (CXL) device. For example, in some data servers, memory capacity and bandwidth may be expanded by adding CXL devices (e.g., in addition to existing memory devices 145). A CXL device may connect with the host system 105 via a peripheral component interconnect express (PCIe) interface and may have one or more DRAM channels. A CXL controller (e.g., the memory system controller 140, a controller different from the memory system controller 140) may be capable of detecting and correcting errors when accessing DRAM. In some cases, the CXL controller may be capable of correcting all bits of a DRAM component (e.g., a die).

Some memory systems 110 may support error detection and correction techniques. For example, the memory system 110 may detect errors when accessing memory, and may correct the errors in one or more regions of memory. The error correction scheme may be a single die data correction (SDDC) scheme or a double die data correction (DDDC) scheme, among other examples. In some examples, the memory system 110 may support memory sparing, which may include replacing unreliable physical memory areas within the memory system with spare memory resources. The memory system may include one or more spare resources (e.g., rows, columns, portions of rows or columns) available per bank or some other granularity of spare resources (e.g., bank, die) available for memory sparing. The memory sparing may be part of a post package repair (PPR) technique, in some cases. However, some memory systems 110 may experience multiple failures per bank or some other quantity of increased errors in memory, such that the spare resources for PPR may not be sufficient to repair and replace the failed memory regions.

As described herein, the memory system 110 may perform further memory repair and recovery using additional resources at a memory system controller, using additional spare resources within the memory according to data compression, or both. For example, a memory system controller (e.g., an application specific integrated circuit (ASIC)) associated with interfacing between the memory system and a host system in accordance with a communication or memory access protocol (e.g., compute express link (CXL)) may include one or more buffers (e.g., memory sparing buffers) that include volatile resources allocated for memory sparing. During a write operation, the memory system controller may determine whether the data to be written is targeting a failed region of memory (e.g., row, column, chunk). If the data is to be written to a failed region of memory, the memory system controller may write the data to a buffer at the controller and may remap the target address to the buffer. When the data is requested to be read, the memory system controller may overwrite data read from the memory region with the data pulled from the buffer. As such, the resources at the memory system controller may be used to expand memory sparing capabilities even if spare resources in the system have been depleted. Additionally, or alternatively, the memory system controller may compress data received from a host system before writing the data to the memory devices. For example, a CXL controller or other type of controller may perform data compression according to a data compression rate. The compression may increase available resources in the memory system. As such, extra rows, columns, and chunks of memory that are available after data compression may be repurposed for memory sparing. The memory system may remap addresses of failed rows, columns, or chunks of memory to the extra rows, columns, and chunks of memory during access operations to extend a lifetime of the system and improve reliability and performance, among other examples.

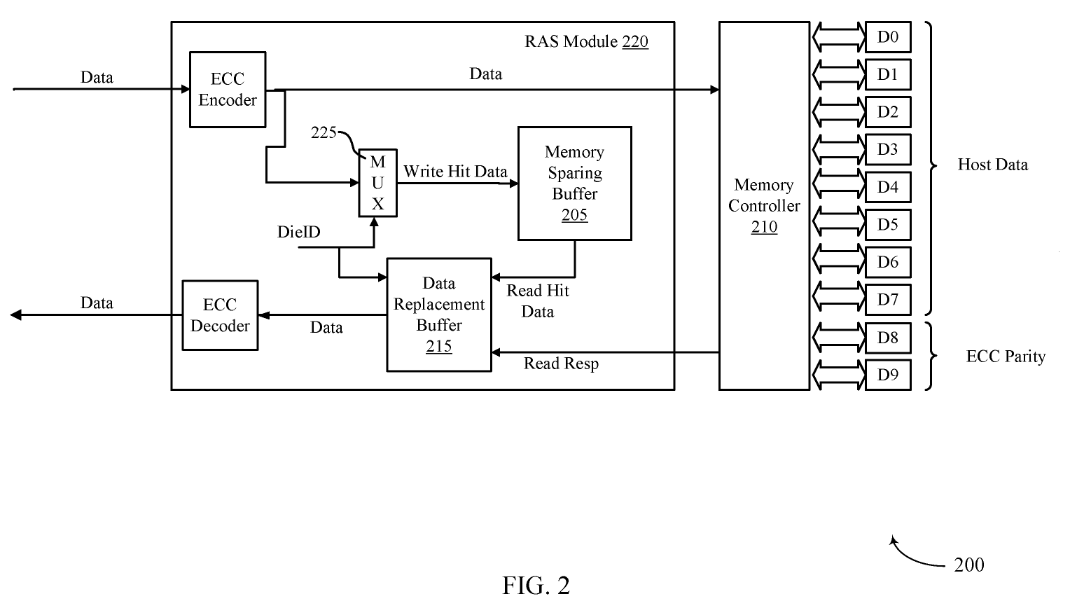

FIG. 2 shows an example of an architecture 200 that supports memory sparing using row remapping and application-specific integrated circuit resources in accordance with examples as disclosed herein. The architecture 200 may implement or may be implemented by aspects of the system 100. For example, the architecture 200 may include DRAM components D0–D9, which may be included in a memory device 145 and/or may be examples of dies, and a reliability availability and serviceability (RAS) module 220 (e.g., an ASIC or other type of module), which may be implemented in a memory system controller 140 or elsewhere in the memory system 110 (e.g., in SRAM).

In some memory systems (e.g., CXL devices), accesses to data (e.g., host data) stored in the memory system may have a particular granularity (e.g., 64 bytes of host data for each access). The data from the host may be encoded using an ECC encoder, and parity bits may be appended to form an 80-byte data chunk with 64 bytes of host data and 16 bytes of parity data, among other example data quantities, which may be written to the memory system. The data may similarly be read from the devices with an 80-byte granularity and decoded to remove 16 bytes of parity information before returning 64 bytes of data to the host system. In an illustrative example, the data may be stored within eight DRAM components (e.g., D0–D7) and error correction code (ECC) parity information associated with the data may be stored in two DRAM components (e.g., D8–D9).

In some examples, the RAS module 220 may implement circuitry which enables memory sparing. For example, the RAS module 220 may include a memory sparing buffer 205 which may be used to store (e.g., temporarily) data from a memory die within the DRAM memory array which has been identified as a failed die (e.g., a no longer reliable die). The data in the memory sparing buffer 205 corresponds to the data that would ordinarily be stored in the failed die. In addition to (e.g., or in place of) storing the data in the identified failed die, the data is stored in the memory sparing buffer 205. The RAS module 220 may communicate with a host system and/or with the memory controller 210 in accordance with a CXL communication protocol.

During a write operation, the RAS module 220 may identify (e.g., using row/column/chunk tag memory and row/column/chunk tag logic) whether a target address of the write operation (e.g., an address requested to be written to) is addressing a failed die (e.g., a die in which a row, column, or a portion of the die, such as a chunk, is no longer reliable or is undergoing repair). For example, the RAS module 220 may receive a request to write data to a target address within a die of the DRAM memory array. The RAS module 220 may determine that the target address of the write operation is addressing a failed die based on comparing the target address with address information (e.g., the address of a row or a portion of the row stored in a tag memory) stored within the RAS module 220. If the RAS module 220 identifies that the target address is addressing a failed die (e.g., identifies that the target address matches the address information stored within the RAS module), the RAS module 220 may select a chunk of data from the overall data stream (e.g., an 8-byte chunk from the 80-bytes of data) using the multiplexer 225, and may write the selected data from the host (e.g., an 8-byte chunk of data intended for the failed die) to the memory sparing buffer 205. The chunk of data may be identified by an ID of the die that is failed (e.g., DieID) that specifies one of the ten dies. In some examples, writing the data to the memory sparing buffer 205 by the RAS module 220 may be in parallel (e.g., at a same time, partially overlapping in time) with a memory controller 210 writing the data to the failed die in the DRAM array (e.g., to the DRAM components D0–D9). For example, the RAS module 220 (e.g., in addition to writing the data to the sparing buffer 205) may forward the data to a second controller (e.g., the memory controller 210 coupled with the dies D0–D9) and the memory controller 210 may write the data to dies within the DRAM memory array according to the target address of the data.

In some other examples, the RAS module 220 may compare the target address of the write operation with the address information stored within the RAS module 220 (e.g., one or more die IDs of failed dies) and may determine that the target address is different from the address information (e.g., is not addressing a failed die ID). In such examples, the RAS module 220 may refrain from writing the data to the memory sparing buffer. The RAS module 220 may forward the data to the memory controller 210 where the memory controller 210 may write the data to within the DRAM memory array according to the target address of the data.

During a read operation, the memory controller 210 may retrieve data from the DRAM array at a target address of the read operation (e.g., an address requested to be read from). The memory controller 210 may forward the retrieved data to the RAS module 220. The RAS module 220 may compare the target address with one or more addresses (e.g., address information) stored in a tag memory. Each of the one or more addresses may specify a portion of memory (e.g., row, column, chunk) in the DRAM array that is no longer reliable and may identify the portion of memory by indicating a row, a column, a bank address, a bank group, a rank, a die ID, or a combination thereof. If the RAS module 220 identifies that the data retrieved from the target address of the DRAM array is from a failed die (e.g., according to the comparison with addresses in the tag memory), the RAS module 220 may replace the data being accessed for the read operation with data from the memory sparing buffer 205. For example, based on identifying that the retrieved data is from a failed die, the data replacement buffer 215 may retrieve the data from the memory sparing buffer 205 and may output the retrieved data to the host (e.g., via an ECC decoder). In some cases, the failed die may be a die in which one or more bytes of ECC parity data are stored with the data. In such cases, the RAS module 220 may also replace the ECC parity data being accessed for the read operation with ECC parity data from the memory sparing buffer 205.

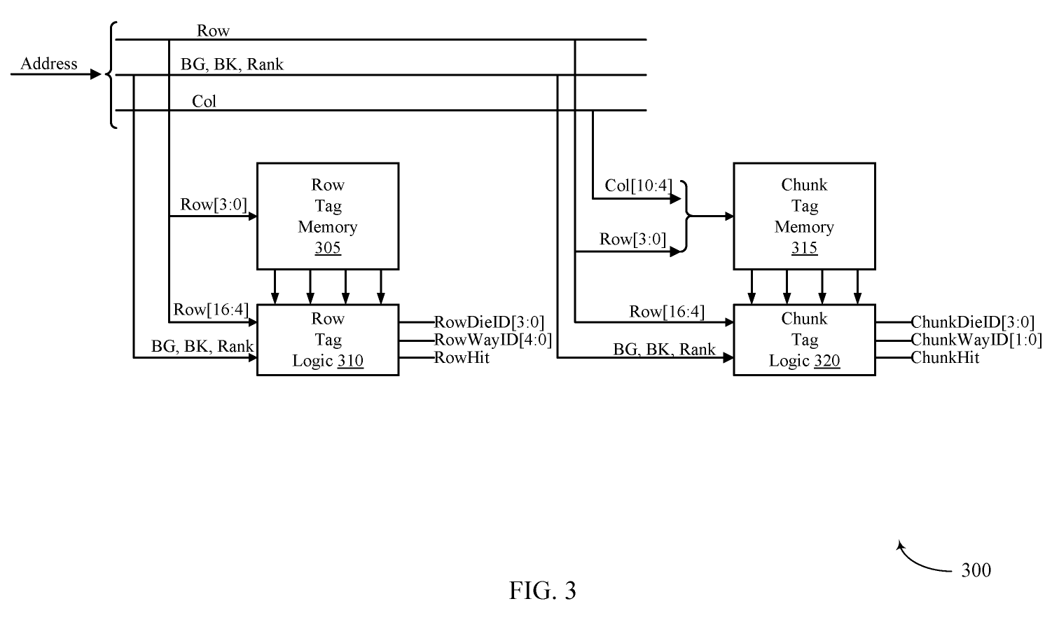

The memory sparing buffer may store the data from multiple addresses of a failed die. Additionally, or alternatively, the memory sparing buffer may store data corresponding to addresses from multiple different failed dies of the DRAM array. In these and other examples where the memory sparing buffer 205 stores data (e.g., replacement data, buffered data) for multiple different memory addresses, the memory sparing buffer 205 may address the data (e.g., according to FIGS. 3-5) such that the memory sparing buffer 205 may identify which data of the failed die to retrieve during a read or write operation. Address information of the portions of memory that are no longer reliable may be stored in a tag memory, and this information may be used for addressing the memory sparing buffer 205. The tag memory within the RAS module 220 may be similar to tag memory of a cache, in some examples, or may implement one or more distinct functionalities relative to a cache. For example, the tag memory within the RAS module 220 for storing address information (e.g., die ID, way ID) for the memory sparing buffer 205 may not implement any cache line eviction in case of a cache miss, in some cases.

For example, the RAS module 220 may identify that data requested to be written is addressing a failed die. The RAS module 220 may retrieve, from a memory (e.g., a row tag memory, a chunk tag memory) of the RAS module 220, the addresses of the memory device 145 that are no longer reliable and the related die identifier that identifies the failed die and a way identifier that identifies a location within the memory sparing buffer 205 used for memory sparing the failed die. The RAS module 220 may write the data to the location in the memory sparing buffer 205 identified by the way identifier. The location in the memory sparing buffer 205 may be based on whether the memory sparing buffer 205 performs memory sparing per row, per column, or per chunk (e.g., a portion of data within a row or column). Accordingly, the RAS module 220 may identify the location in the memory sparing buffer 205 for storing the data based on a granularity flag that indicates whether memory sparing is performed per row, per column, or per chunk (e.g., in combination with the way identifier).

FIG. 3 shows an example of an architecture 300 that supports memory sparing using row remapping and application-specific integrated circuit resources in accordance with examples as disclosed herein. The architecture 300 implement or may be implemented by aspects of the system 100 or the architecture 200.

A DRAM address may be made up of a set of sub-components: a die address (e.g., specifies which die of the multiple dies in a DDR channel for a given rank is addressed), a bank group address, a bank address, a subchannel address, a row address, a rank (e.g., there may be four ranks in a channel), and a column address. A location (e.g., an address) within the memory sparing buffer in which data of a failed die is stored is based on (e.g., mapped to, correlated with) the DRAM address of the portion of memory (e.g., row, column, chunk) within the failed die undergoing repaired or that is no longer reliable.

In some examples, a controller (e.g., the RAS module 220, memory system controller) of the memory system may identify a row which has failed or a chunk that has failed. A memory sparing buffer (e.g., as described with reference to FIG. 2) may be used to store data which is addressed to a failed row, a failed column, or a failed chunk. A row that has failed may be identified by a row tag memory 305 and a chunk that has failed may be identified by a chunk tag memory 315. Though described in the context of failed rows and chunks in examples described herein, aspects of the present disclosure are not so limiting and may be similarly applied to memory sparing of failed columns (e.g., using a column tag memory and column tag logic in place of, or in addition to, the row tag memory 305 and the row tag logic 310). At each access, contents of the row tag memory 305 and the chunk tag memory 315 may be read and compared with the target address being accessed. In the case of a hit (e.g., the target address matches the row tag memory 305 and/or the chunk tag memory 315 corresponding to the target address), the row tag logic 310 or the chunk tag logic may output a die ID of a die to be repaired, a way ID indicating a way (e.g., a data block) to select from the memory sparing buffer, and an indication that the target address triggered a row hit or a chunk hit.

To determine whether the target address is addressing a failed row, a set of address bits (e.g., row address [16:4], bank group address, bank address, and rank) of the target address may be input to the row tag logic 310 and a set of set index bits (e.g., row address [3:0]) of the target address may be input to the row tag memory 305. The row tag memory 305 may output a row address tag and a die ID. The row tag logic 310 may may compare the row address tag with the related target address bits and output whether the target address produces a row hit, and if so, may output a row die ID corresponding to the failed row being addressed and a row way ID indicating which way (e.g., data block) to select from the memory sparing buffer to retrieve or to store the data of the target address.

To determine whether the target address is addressing a failed chunk, a set of address bits (e.g., row address [16:4], bank group address, bank address, and rank) of the target address may be input to the chunk tag logic 320 and a set of set index bits (e.g., column address [10:4], row address [3:0]) of the target address may be input to the chunk tag memory 315. The chunk tag memory 315 may output a chunk address tag and a die ID. The chunk tag logic 320 may may compare the chunk address tag with the related target address bits and output whether the target address produces a chunk hit, and if so, may output a chunk die ID corresponding to the failed chunk being addressed and a chunk way ID indicating which way (e.g., data block) to select from the memory sparing buffer to retrieve or to store the data of the target address.

The tag address bits may be generated based on a determination by the controller that a row or a chunk in a first die within the DRAM memory array has failed. For example, the controller may determine, in accordance with an error correction and detection operations, that a row or a chunk in a first die includes at least a threshold quantity of errors. The controller may store, in a memory of the controller, address information that identifies the row or a chunk in a first die is failed based on the first die including the threshold quantity of errors. The address information may include a set of tag address bits that represent a corresponding address of the first die.

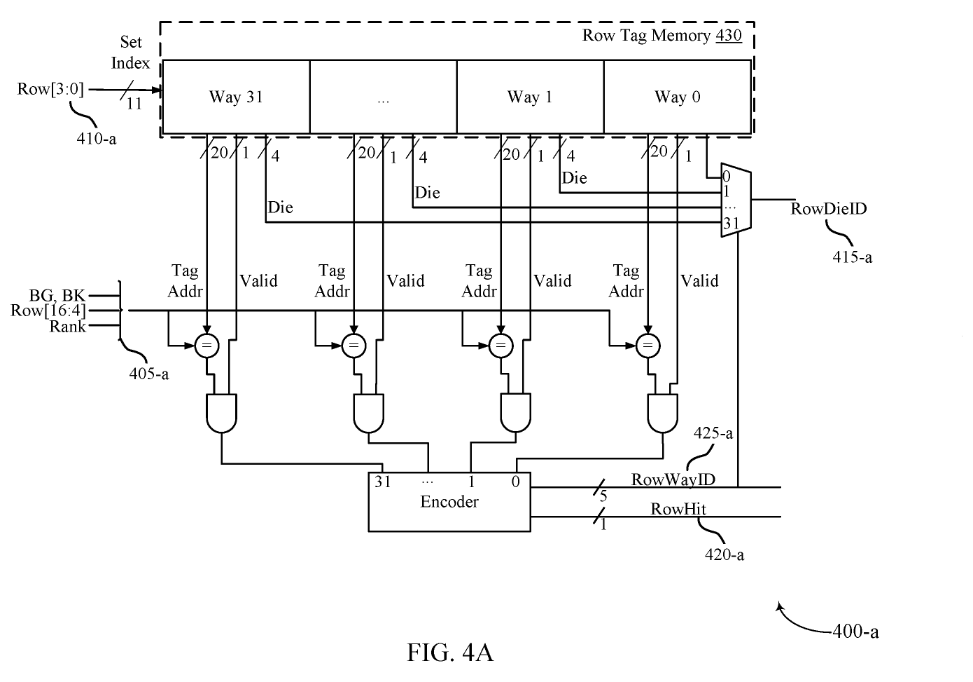

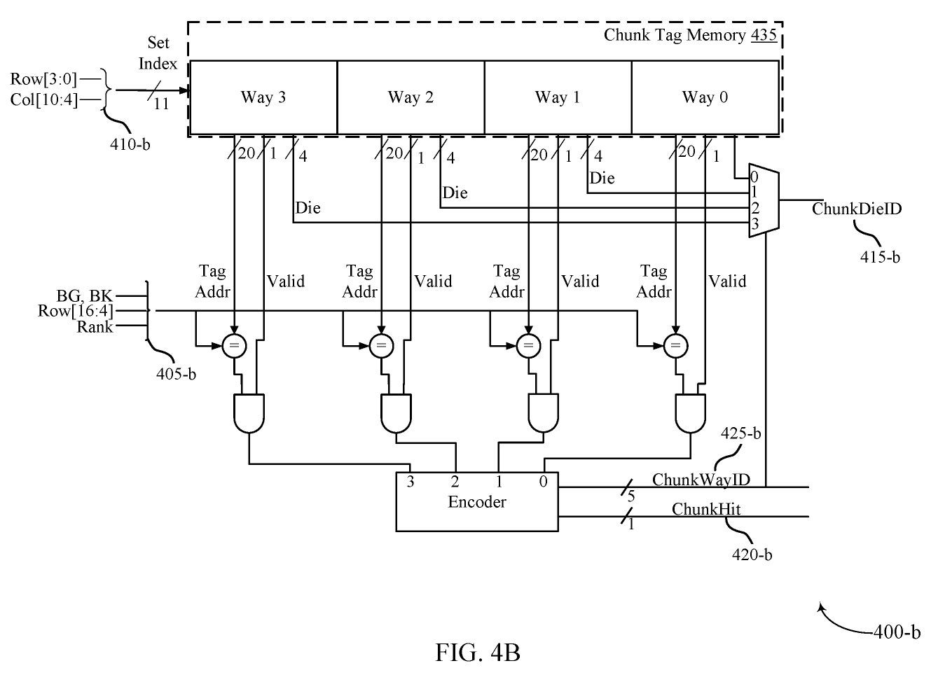

FIGS. 4A and 4B show examples of an encoding scheme 400-a and an encoding scheme 400-b that support memory sparing using row remapping and application-specific integrated circuit resources in accordance with examples as disclosed herein. The encoding scheme 400-a and the encoding scheme 400-b may implement or may be implemented by aspects of the system 100, the architecture 200, or the architecture 300. For example, the encoding scheme 400-a may include a row tag memory 430, which may be an example of a row tag memory 305, and the encoding scheme 400-b may include a chunk tag memory 435, which may be an example of a chunk tag memory as described with reference to FIG. 3.

The encoding scheme 400-a may be an example of the row tag logic 310 as described with reference to FIG. 3. For example, the encoding scheme 400-a may be used to determine the outputs of the row tag logic 310 including the row hit 420-a, the row way ID 425-a, and the row die ID 415-a based on inputs of the address bits 405-a and the set index bits 410-a. The set index bits 410-a may be used as an address (e.g., to identify an address) of the row tag memory 430. As shown in FIG. 4A, the row tag memory 430 may be organized (e.g., structured, partitioned) into 32 ways (e.g., data blocks). Each of the ways may store and/or output a row tag address, a valid bit, and a die ID. The row tag address may be compared with the corresponding bits of the target address. If the row tag address matches the corresponding bits of the target address and if the valid bit corresponding to the row tag address is set to one, a row hit signal may be asserted and the row way ID may identify which way caused the hit. The row way ID may also specify the way (e.g., data blocks, Way 0–31) in the memory sparing buffer in which data of the failed row is stored. Each of the ways may correspond to a die of the DRAM array.

According to the encoding scheme 400-a, a row tag logic 310 may compare the contents of each way of the row tag memory 305 with the corresponding address bits 405-a. If the contents of the way match the address bits 405-a and the contents of the way are valid (e.g., the way is actively storing a row that is no longer reliable or that has failed, the way is enabled), then a row hit is triggered. Based on the row hit being triggered, the encoding scheme 400-a may output a row way ID indicating which way (e.g., 0–31) is to be input to the memory sparing buffer for recovering the row that has failed and a row die ID indicating which die is to be input to the multiplexer 225 or the data replacement buffer 205 for selecting failed die data.

The encoding scheme 400-b may be an example of the chunk tag logic 320 as described with reference to FIG. 3. For example, the encoding scheme 400-b may be used to determine the outputs of the chunk tag logic 320 including the chunk hit 420-b, the chunk way ID 425-b, and the chunk die ID 415-b based on inputs of the address bits 405-b and the set index bits 410-b. The set index bits 410-b may be used as an address (e.g., to identify an address) of the chunk tag memory 435. As shown in FIG. 4B, the chunk tag memory 435 may be organized (e.g., structured, partitioned) into four ways. Each of the ways may store and/or output a chunk tag address, a valid bit, and a die ID. The chunk tag address may be compared with the corresponding bits of the target address. If the chunk tag address matches the corresponding bits of the target address and if the valid bit corresponding to the chunk tag address is set to one, a row hit signal may be asserted and the chunk way ID may identify which way caused the hit. The chunk way ID may also specify the way (e.g., data blocks, Way 0–4) in the memory sparing buffer in which data of the failed row is stored. Each of the ways may correspond to a die of the DRAM array.

According to the encoding scheme 400-b, a chunk tag logic 320 may compare the contents of each way of the chunk tag memory 435 with the corresponding address bits 405-b. If the contents of the way match the address bits 405-b and the contents of the way are valid (e.g., the way is actively storing a chunk that is no longer reliable or that has failed, the way is enabled), then a chunk hit is triggered. Based on the chunk hit being triggered, the encoding scheme 400-b may output a chunk way ID indicating which way (e.g., 0–4) is to be input to the memory sparing buffer for recovering the missing chunk and a chunk die ID indicating which die is to be input to the multiplexer 225 or the data replacement buffer 205 for selecting failed die data.

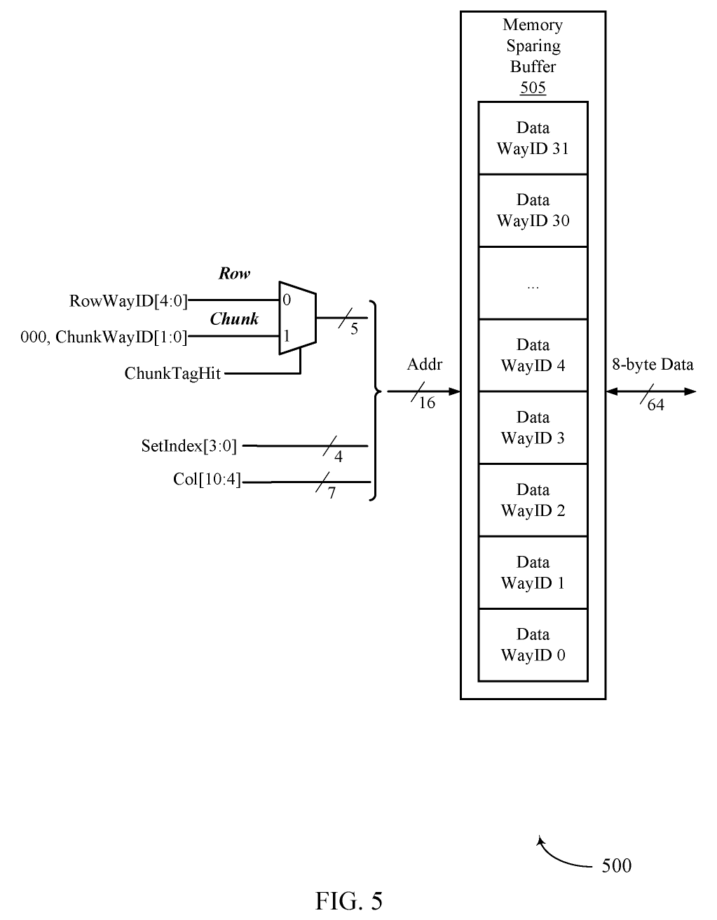

FIG. 5 shows an example of an architecture 500 that supports memory sparing using row remapping and application-specific integrated circuit resources in accordance with examples as disclosed herein. The architecture 500 may implement or may be implemented by aspects of the system 100 or the architecture 200. For example, the architecture 500 may include a memory sparing buffer 505, which may be an example of a memory sparing buffer 205 as described with reference to FIG. 2.

The architecture 500 may enable a RAS module (e.g., a RAS module 220, a memory system controller 140, an ASIC) to retrieve contents from the memory sparing buffer 505 which correspond to a target address. For example, by addressing the memory sparing buffer with a row way ID or a chunk way ID (e.g., as described with reference to FIGS. 3 and 4) in combination with the set index (e.g., row address [3:0]) and column (e.g., column address [10:4]) bits, a way (e.g., data block) where the data for the target address is stored in the memory sparing buffer 505 may be identified.

As described herein, the memory sparing buffer 505 may be used to store replacement data for a failed row or a failed chunk. Accordingly, an indication of whether the target address is directed to a failed row or a failed chunk may be used to determine whether a row way ID or a chunk way ID is the correct input to the memory sparing buffer 505. In some examples, such an indication may be referred to as a chunk tag hit. For example, if the chunk tag hit is 1, then the chunk way ID may be input to the memory sparing buffer 505, otherwise if the chunk tag hit is 0, then the row way ID may be input to the memory sparing buffer 505.

For a given set (e.g., as identified by the set index bits), any way ID may be used to repair (e.g., replace, substitute for) a row (e.g., a 1-Kbyte row) while a subset of the way IDs (e.g., Way IDs 0–3, no more than four ways) may be used to repair a chunk (e.g., an 8-byte chunk).

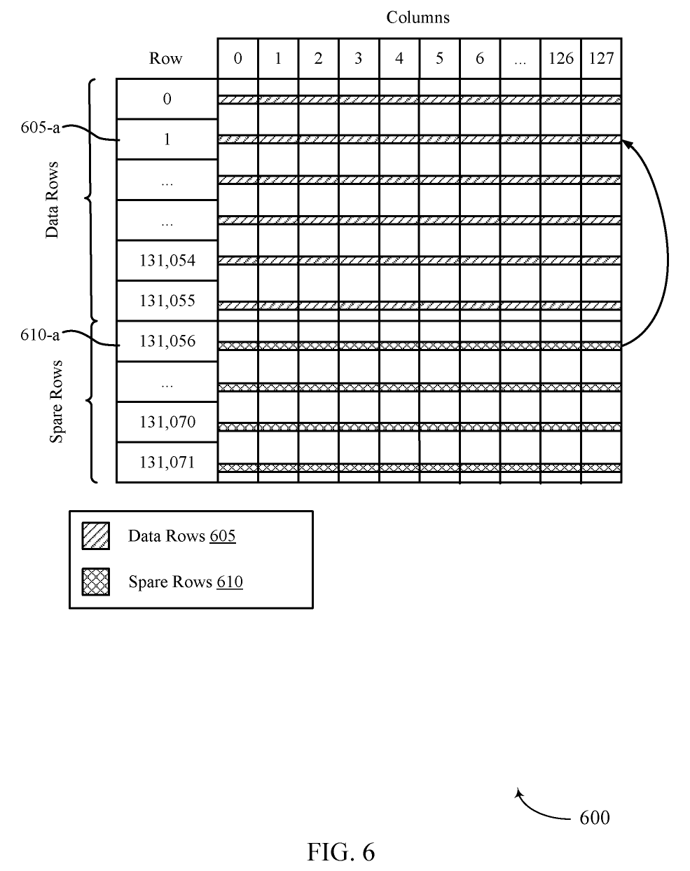

FIG. 6 shows an example of an architecture 600 that supports memory sparing using row remapping and application-specific integrated circuit resources in accordance with examples as disclosed herein. The architecture 600 may implement or may be implemented by aspects of the system 100. For example, the architecture 600 may include rows and columns of a memory array 155 in a memory device 145.

In some memory systems (e.g., CXL devices), a memory system controller (e.g., a RAS module 220, a memory system controller 140) may compress data before or during storing of the data into memory. The memory system controller may use one of multiple compression algorithms to compress the data, and a compression ratio may vary based on the compression algorithm used and one or more characteristics of the data being compressed. As used herein, compressed data may refer to data that has been modified or otherwise altered to be smaller in size (e.g., relative to its original size). For example, a memory system controller may implement one or more data compression algorithms which cause the data to be encoded, restructured (e.g., patterned), or otherwise modified to reduce its size.

Based on compressing the data, a capacity available for storing data may be larger than a physical capacity of the memory array. The capacity available for storing data may be based on an actual compression rate achieved when compressing the data, an effectiveness of compressing the data, or both. For example, in some cases a memory controller may use a relatively simple compression algorithm to compress the data and the capacity available for storing data may be relatively small. In other cases, the memory controller may use more sophisticated compression algorithm to compress the data and the capacity available for storing data may be relatively large.

In some examples, the memory system may indicate (e.g., via a register) its capacity that is available to a host system for storing data. The memory system may indicate its capacity with a granularity of 256 megabytes, or some other granularity. In some cases, however, the memory system may reserve some rows as spare rows for memory sparing. In such cases, the value that the memory system indicates (e.g., advertises) for its available capacity may be less than an actual capacity of the memory system for storing data. For example, the memory system may have a capacity for storing one gigabyte of data. The memory system may indicate an available capacity of 1020 megabytes to a host system, and the remaining 4 megabytes may be reserved as spare rows for memory sparing.

The quantity of spare rows 610 that is available for memory sparing may be independent form an available logical space within the memory system. The quantity of spare rows 610 may be available on a per-bank basis. For example, each bank of the memory array may have a plurality of spare rows 610 available which are specific to the particular bank. The spare rows 610 may be different from PPR resources within the memory system. Though described in the context of failed rows in examples described herein, aspects of the present disclosure are not so limiting and may be similarly applied to memory sparing of failed columns (e.g., using spare columns in place of, or in addition to, spare rows 610).

The memory system may be configured with a first quantity (e.g., 131,056) of data rows 605 and a second quantity (e.g., 16) of spare rows 610. The memory system may use the data rows 605 for storing data from the host system. Both the data rows 605 and the spare rows 610 may be included in a DRAM memory array. In cases where the memory system identifies a failed data row 605-a (e.g., data row 605 drops below a threshold reliability, exceeds a threshold quantity of errors, undergoes maintenance, etc.), the memory system may substitute a spare row 610-a for the failed data row 605-a.

Based on performing the substitution, any subsequent accesses which would, prior the substitution, access memory cells of the data row 605-a will access memory cells of the data row 610-a instead. For example, the memory system controller may perform a remapping procedure to cause a spare row 610 to take the place of (e.g., replace, substitute for) a failed data row 605-a. In this way, the memory system controller may remap a first (e.g., original) address of the data with a second address associated with the row 610-a that is different from the failed row 605-a. Remapping the first address to the second address may be based on an identification that the first address is invalid. Subsequent accesses which request data from the first address may access the data in the row 610-a in accordance with the remapping of the first address to the second address.

The memory system may store a set of tag addresses which indicate addresses of DRAM rows which are no longer reliable (e.g., are failed addresses, are addresses undergoing repair). The memory system may receive a request to access data within an address and may compare the address to the set of tag addresses to determine if the address is undergoing repair. For example, the memory system may select a tag memory using a bank group, a bank address, and a rank associated with the requested address. The tag memory may output one or more tag addresses and valid bit pairs (one for each way). The one or more tag addresses may be compared with the target address of the request. If the target address matches one of the one or more tag addresses and the valid bit for that tag address is set to one, the memory system may output a validity indication that indicates the address is undergoing repair (e.g., that data from a spare row replaces data stored at the address) and an identifier of a spare row in the memory system which is used to remap the first address to a second address which addresses the spare row. The identifier of the spare row may point to the row 610-a and may replace a pointer to the row 605-a in the second address.

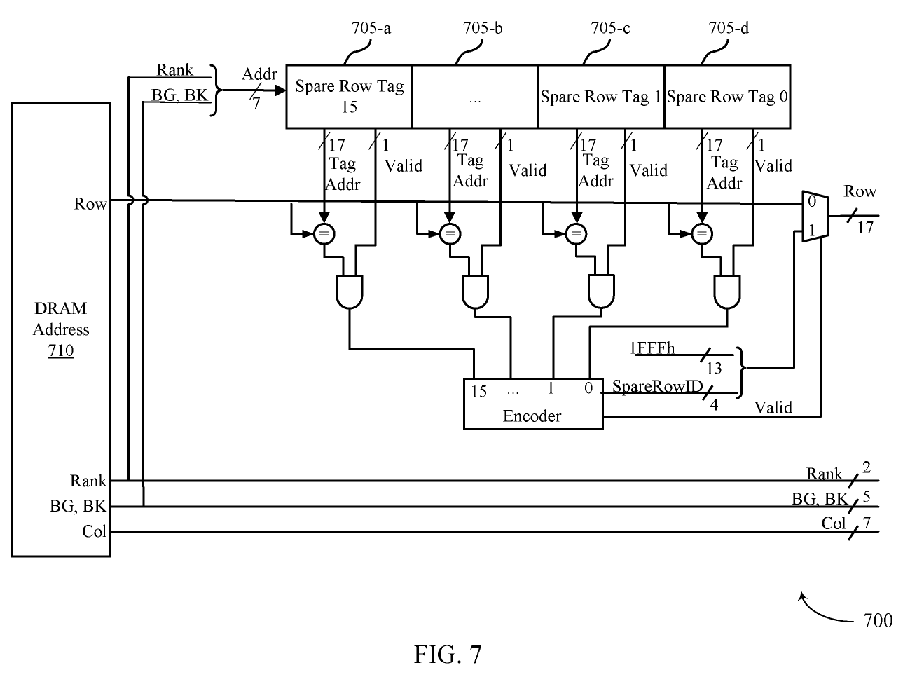

FIG. 7 shows an example of an encoding scheme 700 that supports memory sparing using row remapping and application-specific integrated circuit resources in accordance with examples as disclosed herein. The encoding scheme 700 may implement or may be implemented by aspects of the system 100. For example, the encoding scheme 700 may be implemented by a memory system controller 140 or a local controller 150 to perform a remapping of rows within a memory device array 155.

A memory controller may perform a remapping procedure to replace a failed row (e.g., a failed data row 605-a) with a spare row (e.g., a spare row 610-a) according to the encoding scheme 700. For example, the memory controller may identify a DRAM address 710 (e.g., based on receiving a command for the address, performing an access to the address, or both). The DRAM address 710 may include a row, a rank, a bank group, a bank, and a column. The memory controller may determine whether the row in the DRAM address 710 stores the data addressed by the DRAM address 710 or whether a spare row (e.g., a replacement row, a substitute row) stores the data.

To determine whether a spare row stores the target data, the memory controller may compare the row address with a set of tag addresses that each correspond to a respective spare row of a set of spare rows (e.g., 16 spare rows) of (e.g., allocated to) an individual bank of the DRAM memory array. For example, the memory system may allocate a set of spare rows (e.g., 16 spare rows) for each bank in the memory array. Using the bank that is identified by the DRAM address 710 (e.g., identified by a bank address, a bank group address, and a rank of the DRAM address 710), the memory controller may identify which rows of the identified bank have been replaced with spare rows by reading the contents of spare row tags 705 (e.g., a spare row tag 705-a, a spare row tag 705-b, a spare row tag 705-c, spare row tag 705-d). A spare row tag 705 may include a tag address, which indicates the row of the identified bank for which the spare row (e.g., the spare row 15) is replacing. The spare row tag 705 may also include a valid bit which indicates whether the spare row is being used as a replacement (e.g., or if the spare row is inactive, not storing data).

The memory controller may compare the row of the DRAM address 710 with the tag address of each of the spare row tags 705 to determine whether a replacement row exists for the DRAM address 710. If the row of the DRAM address 710 matches the tag address of one of the spare row tags 705 and the valid bit of the spare row tag 705 indicates that the corresponding spare row is active (e.g., valid) as a replacement row, the memory system controller may determine that the row of the DRAM address 710 has been replaced with the spare row indicated by the spare row tag 705. In this case, the memory controller may use an updated address for carrying out accesses to the DRAM address 710. For example, the memory controller may switch the row that is accessed by the DRAM address 710 to include a row address of the spare row that has replaced the failed row. A row address of the spare row may be based on an identifier (e.g., 0–16) of the spare row. For example, the row address may be a combination of a predetermined offset value (e.g., 1FFFh) with the spare row ID.

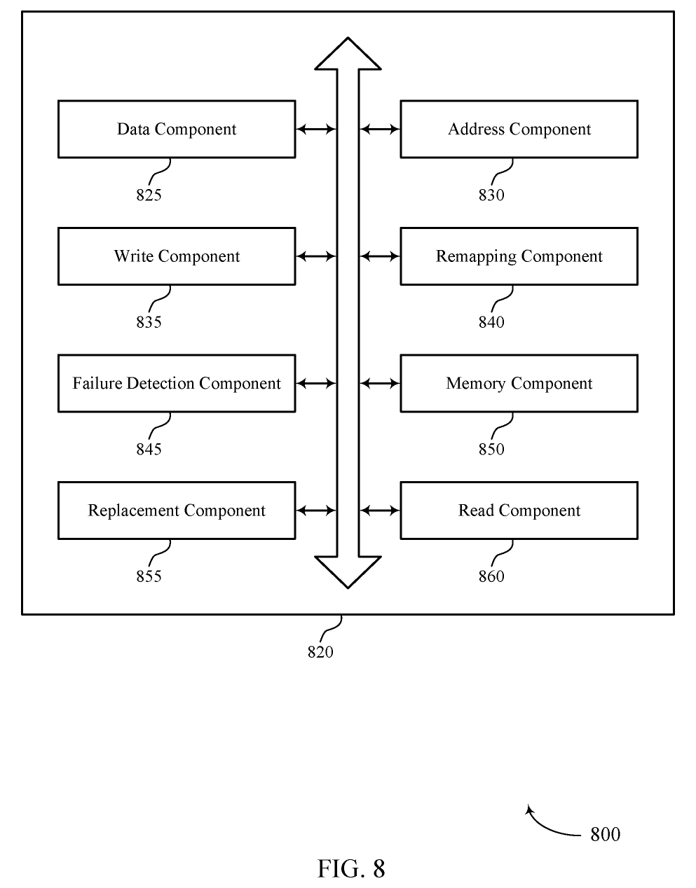

FIG. 8 shows a block diagram 800 of a memory system 820 that supports memory sparing using row remapping and application-specific integrated circuit resources in accordance with examples as disclosed herein. The memory system 820 may be an example of aspects of a memory system as described with reference to FIGS. 1 through 7. The memory system 820, or various components thereof, may be an example of means for performing various aspects of memory sparing using row remapping and application-specific integrated circuit resources as described herein. For example, the memory system 820 may include a data component 825, an address component 830, a write component 835, a remapping component 840, a failure detection component 845, a memory component 850, a replacement component 855, a read component 860, or any combination thereof. Each of these components, or components of subcomponents thereof (e.g., one or more processors, one or more memories), may communicate, directly or indirectly, with one another (e.g., via one or more buses).

The data component 825 may be configured as or otherwise support a means for receiving, at a controller of the memory system, a request to write data to one or more addresses within one or more dies of the memory system. The address component 830 may be configured as or otherwise support a means for comparing the one or more addresses with address information stored within the controller, where the address information indicates a first die, of the one or more dies, that is a failed die. Additionally, or alternatively, the address information may indicate an unreliable memory region (e.g., a row, column, or chunk, a memory region undergoing repair or that is repaired by memory sparing) within the failed die. The write component 835 may be configured as or otherwise support a means for determining whether to write the data to a buffer within the controller in accordance with the comparing of the one or more addresses with the address information that indicates the failed die, the buffer associated with memory sparing the failed die.

In some examples, the write component 835 may be configured as or otherwise support a means for writing, in accordance with the one or more addresses being different from the address information, the data to the one or more dies.

In some examples, the data component 825 may be configured as or otherwise support a means for transmitting, from the controller to a second controller coupled with the one or more dies, the data and the one or more addresses, where writing the data to the one or more dies includes writing, by the second controller, the data to the one or more dies in accordance with the one or more addresses.

In some examples, the write component 835 may be configured as or otherwise support a means for writing, in accordance with the one or more addresses matching the address information, the data to the buffer.

In some examples, the memory component 850 may be configured as or otherwise support a means for retrieving, from a memory of the controller of the memory system in accordance with the one or more addresses matching the address information, a die identifier that identifies the failed die and a way identifier that identifies a location within the buffer, where writing the data to the buffer includes writing the data to the location indicated by the way identifier.

In some examples, to support writing the data to the buffer, the write component 835 may be configured as or otherwise support a means for writing the data to a location in the buffer, where the location is in accordance with the address information in a memory of the controller of the memory system and a granularity flag that indicates whether memory sparing is performed per row, per column, or per data chunk, where a data chunk includes a portion of data within a portion of a row or a column of the one or more dies.

In some examples, the data component 825 may be configured as or otherwise support a means for receiving, at the controller, second data that is read from the one or more addresses within the one or more dies in accordance with a read operation to the one or more addresses. In some examples, the replacement component 855 may be configured as or otherwise support a means for replacing the second data with the data from the buffer in accordance with the one or more addresses matching the address information. In some examples, the read component 860 may be configured as or otherwise support a means for transmitting, to a host system, the data in accordance with replacing the second data.

In some examples, the address component 830 may be configured as or otherwise support a means for generating the address information in accordance with an address of the failed die and a granularity associated with second data stored to the failed die, where the address information includes a plurality of tag bits that indicate a memory die address, a bank group address, a bank address, a subchannel address, a row address, and a rank associated with a respective row of the second data in accordance with the granularity being a row granularity.

In some examples, the address component 830 may be configured as or otherwise support a means for generating the address information in accordance with an address of the failed die and a granularity associated with second data stored to the failed die, where the address information includes a plurality of tag bits that indicate a memory die address, a bank group address, a bank address, a subchannel address, a row address, a rank, and a column address associated with a respective data chunk of the second data in accordance with the granularity being a data chunk granularity, and where a data chunk includes a portion of data within a portion of a row of the one or more dies.

In some examples, the failure detection component 845 may be configured as or otherwise support a means for determining, in accordance with an error correction and detection operation, that the first die includes at least a threshold quantity of errors. In some examples, the failure detection component 845 may be configured as or otherwise support a means for storing, in a memory of the controller, the address information that identifies the first die is the failed die in accordance with detecting the threshold quantity of errors in the first die, where the address information is stored as a plurality of tag bits that represent a corresponding address of the first die.

In some examples, the controller includes an application-specific integrated circuit associated with a compute express link communication protocol.

In some examples, the address component 830 may be configured as or otherwise support a means for receiving an access command for data stored within a first row of the memory system, where the access command includes a first address of the data. The remapping component 840 may be configured as or otherwise support a means for remapping, in accordance with the access command, the first address of the data to a second address associated with a second row of the memory system that is different from the first row, where remapping the first address to the second address is in accordance with the first address being invalid. In some examples, the data component 825 may be configured as or otherwise support a means for accessing, in accordance with the remapping and in response the access command, the data in the second row of the memory system.

In some examples, to support remapping the first address to the second address, the address component 830 may be configured as or otherwise support a means for comparing the first address with a plurality of tag addresses stored by the memory system, where the plurality of tag addresses indicate invalid addresses within the memory system. In some examples, to support remapping the first address to the second address, the remapping component 840 may be configured as or otherwise support a means for outputting, in accordance with the comparing, an invalidity indication that indicates the first address is invalid. In some examples, to support remapping the first address to the second address, the remapping component 840 may be configured as or otherwise support a means for outputting, in accordance with the comparing, an identifier of a spare row in the memory system, where remapping the first address to the second address is in accordance with the invalidity indication and the identifier of the spare row.

In some examples, the identifier of the spare row points to the second row and replaces a pointer to the first row in the second address.

In some examples, to support comparing the first address with the plurality of tag addresses, the address component 830 may be configured as or otherwise support a means for comparing a bank group, a bank address, and a rank included in the first address with the plurality of tag addresses.

In some examples, the data component 825 may be configured as or otherwise support a means for receiving one or more write commands indicating second data. In some examples, the data component 825 may be configured as or otherwise support a means for compressing the second data indicated via the one or more write commands according to the compression rate before storing the compressed second data to one or more data rows in the memory system, the one or more data rows different from the plurality of spare rows, wherein a quantity of the one or more spare rows is independent from an available logical space within the memory system.

In some examples, the plurality of spare rows are different from post package repair resources within the memory system (e.g., a memory device, within a DRAM array).

In some examples, the first address and the second address include a same column address, a same rank, a same bank address, and different row addresses.

In some examples, the described functionality of the memory system 820, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 820, or various components thereof, may be implemented at least in part by instructions (e.g., stored in memory, non-transitory computer-readable medium) executable by such at least one processor.

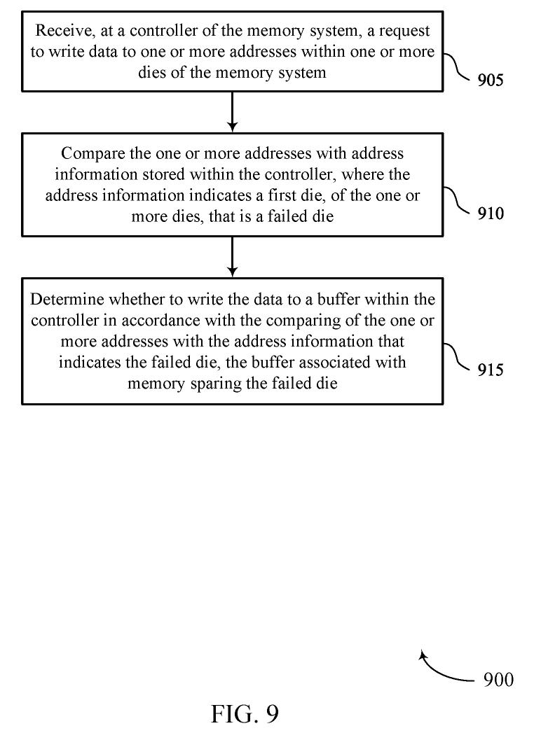

FIG. 9 shows a flowchart illustrating a method 900 that supports memory sparing using row remapping and application-specific integrated circuit resources in accordance with examples as disclosed herein. The operations of method 900 may be implemented by a memory system or its components as described herein. For example, the operations of method 900 may be performed by a memory system as described with reference to FIGS. 1 through 8. In some examples, a memory system may execute a set of instructions to control the functional elements of the device to perform the described functions. Additionally, or alternatively, the memory system may perform aspects of the described functions using special-purpose hardware.

At 905, the method may include receiving, at a controller of the memory system, a request to write data to one or more addresses within one or more dies of the memory system. In some examples, aspects of the operations of 905 may be performed by a data component 825 as described with reference to FIG. 8.

At 910, the method may include comparing the one or more addresses with address information stored within the controller, where the address information indicates a first die, of the one or more dies, that is a failed die. In some examples, aspects of the operations of 910 may be performed by an address component 830 as described with reference to FIG. 8.

At 915, the method may include determining whether to write the data to a buffer within the controller in accordance with the comparing of the one or more addresses with the address information that indicates the failed die, the buffer associated with memory sparing the failed die. In some examples, aspects of the operations of 915 may be performed by a write component 835 as described with reference to FIG. 8.

In some examples, an apparatus as described herein may perform a method or methods, such as the method 900. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving, at a controller of the memory system, a request to write data to one or more addresses within one or more dies of the memory system; comparing the one or more addresses with address information stored within the controller, where the address information indicates a first die, of the one or more dies, that is a failed die; and determining whether to write the data to a buffer within the controller in accordance with the comparing of the one or more addresses with the address information that indicates the failed die, the buffer associated with memory sparing the failed die.

Aspect 2: The method, apparatus, or non-transitory computer-readable medium of aspect 1, further including operations, features, circuitry, logic, means, or instructions, or any combination thereof for writing, in accordance with the one or more addresses being different from the address information, the data to the one or more dies.

Aspect 3: The method, apparatus, or non-transitory computer-readable medium of aspect 2, further including operations, features, circuitry, logic, means, or instructions, or any combination thereof for transmitting, from the controller to a second controller coupled with the one or more dies, the data and the one or more addresses, where writing the data to the one or more dies includes writing, by the second controller, the data to the one or more dies in accordance with the one or more addresses.

Aspect 4: The method, apparatus, or non-transitory computer-readable medium of any of aspects 1 through 3, further including operations, features, circuitry, logic, means, or instructions, or any combination thereof for writing, in accordance with the one or more addresses matching the address information, the data to the buffer.

Aspect 5: The method, apparatus, or non-transitory computer-readable medium of aspect 4, further including operations, features, circuitry, logic, means, or instructions, or any combination thereof for retrieving, from a memory of the controller of the memory system in accordance with the one or more addresses matching the address information, a die identifier that identifies the failed die and a way identifier that identifies a location within the buffer, where writing the data to the buffer includes writing the data to the location indicated by the way identifier.

Aspect 6: The method, apparatus, or non-transitory computer-readable medium of any of aspects 4 through 5, where writing the data to the buffer includes operations, features, circuitry, logic, means, or instructions, or any combination thereof for writing the data to a location in the buffer, where the location is in accordance with the address information in a memory of the controller of the memory system and a granularity flag that indicates whether memory sparing is performed per row, per column, or per data chunk, where a data chunk includes a portion of data within a portion of a row or a column of the one or more dies.

Aspect 7: The method, apparatus, or non-transitory computer-readable medium of any of aspects 4 through 6, further including operations, features, circuitry, logic, means, or instructions, or any combination thereof for receiving, at the controller, second data that is read from the one or more addresses within the one or more dies in accordance with a read operation to the one or more addresses; replacing the second data with the data from the buffer in accordance with the one or more addresses matching the address information; and transmitting, to a host system, the data in accordance with replacing the second data.

Aspect 8: The method, apparatus, or non-transitory computer-readable medium of any of aspects 1 through 7, further including operations, features, circuitry, logic, means, or instructions, or any combination thereof for generating the address information in accordance with an address of the failed die and a granularity associated with second data stored to the failed die, where the address information includes a plurality of tag bits that indicate a memory die address, a bank group address, a bank address, a subchannel address, a row address, and a rank associated with a respective row of the second data in accordance with the granularity being a row granularity.

Aspect 9: The method, apparatus, or non-transitory computer-readable medium of any of aspects 1 through 8, further including operations, features, circuitry, logic, means, or instructions, or any combination thereof for generating the address information in accordance with an address of the failed die and a granularity associated with second data stored to the failed die, where the address information includes a plurality of tag bits that indicate a memory die address, a bank group address, a bank address, a subchannel address, a row address, a rank, and a column address associated with a respective data chunk of the second data in accordance with the granularity being a data chunk granularity, and where a data chunk includes a portion of data within a portion of a row of the one or more dies.

Aspect 10: The method, apparatus, or non-transitory computer-readable medium of any of aspects 1 through 9, further including operations, features, circuitry, logic, means, or instructions, or any combination thereof for determining, in accordance with an error correction and detection operation, that the first die includes at least a threshold quantity of errors and storing, in a memory of the controller, the address information that identifies the first die is the failed die in accordance with detecting the threshold quantity of errors in the first die, where the address information is stored as a plurality of tag bits that represent a corresponding address of the first die.

Aspect 11: The method, apparatus, or non-transitory computer-readable medium of any of aspects 1 through 10, where the controller includes an application-specific integrated circuit associated with a compute express link communication protocol.

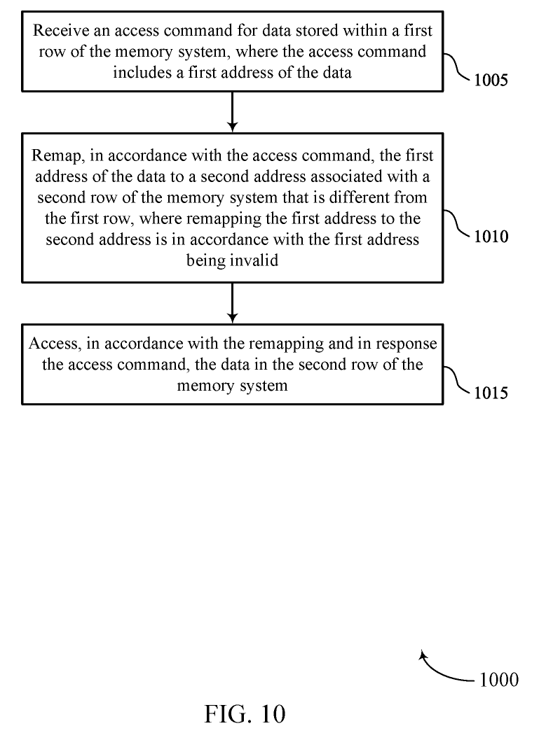

FIG. 10 shows a flowchart illustrating a method 1000 that supports memory sparing using row remapping and application-specific integrated circuit resources in accordance with examples as disclosed herein. The operations of method 1000 may be implemented by a memory system or its components as described herein. For example, the operations of method 1000 may be performed by a memory system as described with reference to FIGS. 1 through 8. In some examples, a memory system may execute a set of instructions to control the functional elements of the device to perform the described functions. Additionally, or alternatively, the memory system may perform aspects of the described functions using special-purpose hardware.

At 1005, the method may include receiving an access command for data stored within a first row of the memory system, where the access command includes a first address of the data. In some examples, aspects of the operations of 1005 may be performed by an address component 830 as described with reference to FIG. 8.

At 1010, the method may include remapping, in accordance with the access command, the first address of the data to a second address associated with a second row of the memory system that is different from the first row, where remapping the first address to the second address is in accordance with the first address being invalid. In some examples, aspects of the operations of 1010 may be performed by a remapping component 840 as described with reference to FIG. 8.

At 1015, the method may include accessing, in accordance with the remapping and in response the access command, the data in the second row of the memory system. In some examples, aspects of the operations of 1015 may be performed by a data component 825 as described with reference to FIG. 8.

In some examples, an apparatus as described herein may perform a method or methods, such as the method 1000. The apparatus may include features, circuitry, logic, means, or instructions (e.g., a non-transitory computer-readable medium storing instructions executable by a processor), or any combination thereof for performing the following aspects of the present disclosure:

Aspect 12: A method, apparatus, or non-transitory computer-readable medium including operations, features, circuitry, logic, means, or instructions, or any combination thereof for receiving an access command for data stored within a first row of the memory system, where the access command includes a first address of the data; remapping, in accordance with the access command, the first address of the data to a second address associated with a second row of the memory system that is different from the first row, where remapping the first address to the second address is in accordance with the first address being invalid; and accessing, in accordance with the remapping and in response the access command, the data in the second row of the memory system.

Aspect 13: The method, apparatus, or non-transitory computer-readable medium of aspect 12, where remapping the first address to the second address includes operations, features, circuitry, logic, means, or instructions, or any combination thereof for comparing the first address with a plurality of tag addresses stored by the memory system, where the plurality of tag addresses indicate invalid addresses within the memory system; outputting, in accordance with the comparing, an invalidity indication that indicates the first address is invalid; and outputting, in accordance with the comparing, an identifier of a spare row in the memory system, where remapping the first address to the second address is in accordance with the invalidity indication and the identifier of the spare row.

Aspect 14: The method, apparatus, or non-transitory computer-readable medium of aspect 13, where the identifier of the spare row points to the second row and replaces a pointer to the first row in the second address.

Aspect 15: The method, apparatus, or non-transitory computer-readable medium of any of aspects 13 through 14, where comparing the first address with the plurality of tag addresses includes operations, features, circuitry, logic, means, or instructions, or any combination thereof for comparing a bank group, a bank address, and a rank included in the first address with the plurality of tag addresses.

Aspect 16: The method, apparatus, or non-transitory computer-readable medium of any of aspects 12 through 15, further including operations, features, circuitry, logic, means, or instructions, or any combination thereof for receiving one or more write commands indicating second data and compressing the second data indicated via the one or more write commands according to the compression rate before storing the compressed second data to one or more data rows in the memory system, the one or more data rows different from the plurality of spare rows, wherein a quantity of the one or more spare rows is independent from an available logical space within the memory system.

Aspect 17: The method, apparatus, or non-transitory computer-readable medium of any of aspect 16, where the plurality of spare rows are different from post package repair resources within the memory system.

Aspect 18: The method, apparatus, or non-transitory computer-readable medium of any of aspects 12 through 17, where the first address and the second address include a same column address, a same rank, a same bank address, and different row addresses.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 19: An apparatus, including: one or more dies configured to store data; a first controller coupled with the one or more dies and configured to access the one or more dies; and a second controller coupled with the first controller and a host system and configured to interface between the host system and the first controller, where the second controller includes: a memory configured to store address information that identifies a die of the one or more dies that is a failed die; a buffer configured to store data associated with the failed die; and a multiplexer configured to receive the data and select, in accordance with the address information in the memory, whether to write the data to the buffer or to transfer the data to the first controller for storage in the one or more dies.

Aspect 20: The apparatus of aspect 19, where the memory further includes: circuitry configured to compare one or more addresses associated with an access operation with the address information and output, in accordance with the one or more addresses matching the address information, a die identifier that indicates a die associated with the one or more addresses and a way identifier that indicates a location associated with the one or more addresses in the buffer.

Aspect 21: The apparatus of any of aspects 19 through 20, where the second controller further includes: a second buffer configured to store second data associated with a second failed die of the one or more dies.

Aspect 22: The apparatus of any of aspects 19 through 21, where the second controller further includes: a second buffer configured to retrieve the data from the buffer and configured to replace second data read from the one or more dies during a read operation with the data retrieved from the buffer in accordance with the second data being read from the failed die.

Aspect 23: The apparatus of any of aspects 19 through 22, where the second controller further includes: encoding and decoding circuitry configured to encode the data with parity information before the data is transferred to the first controller or to decode the data and the parity information before the data is transferred to the host system.

Aspect 24: The apparatus of any of aspects 19 through 23, where the buffer includes a static random access memory buffer.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
receive, at a controller of the memory system, a request to write data to one or more addresses within one or more dies of the memory system;
compare the one or more addresses with address information stored within the controller, wherein the address information indicates a first die, of the one or more dies, that is a failed die; and
determine whether to write the data to a buffer within the controller in accordance with comparing the one or more addresses with the address information that indicates the failed die, the buffer associated with memory sparing the failed die.

2. The memory system of claim 1, wherein the processing circuitry is further configured to cause the memory system to:
write, in accordance with the one or more addresses being different from the address information, the data to the one or more dies.

3. The memory system of claim 2, wherein the processing circuitry is further configured to cause the memory system to:
transmit, from the controller to a second controller coupled with the one or more dies, the data and the one or more addresses, and wherein, to write the data to the one or more dies, the processing circuitry is configured to cause the memory system to:
write, by the second controller, the data to the one or more dies in accordance with the one or more addresses.

4. The memory system of claim 1, wherein the processing circuitry is further configured to cause the memory system to:
write, in accordance with the one or more addresses matching the address information, the data to the buffer.

5. The memory system of claim 4, wherein the processing circuitry is further configured to cause the memory system to:
retrieve, from a memory of the controller of the memory system in accordance with the one or more addresses matching the address information, a die identifier that identifies the failed die and a way identifier that identifies a location within the buffer, wherein writing the data to the buffer comprises writing the data to the location indicated by the way identifier.

6. The memory system of claim 4, wherein, to write the data to the buffer, the processing circuitry is configured to cause the memory system to:
write the data to a location in the buffer, wherein the location is in accordance with the address information in a memory of the controller of the memory system and a granularity flag that indicates whether memory sparing is performed per row, per data chunk, or per column, wherein a data chunk comprises a portion of data within a portion of a row or a column of the one or more dies.

7. The memory system of claim 4, wherein the processing circuitry is further configured to cause the memory system to:
receive, at the controller, second data that is read from the one or more addresses within the one or more dies in accordance with a read operation to the one or more addresses;
replace the second data with the data from the buffer in accordance with the one or more addresses matching the address information; and
transmit, to a host system, the data in accordance with replacing the second data.

8. The memory system of claim 1, wherein the processing circuitry is further configured to cause the memory system to:
generate the address information in accordance with an address of the failed die and a granularity associated with second data stored to the failed die, wherein the address information comprises a plurality of tag bits that indicate a memory die address, a bank group address, a bank address, a subchannel address, a row address, and a rank associated with a respective row of the second data in accordance with the granularity being a row granularity.

9. The memory system of claim 1, wherein the processing circuitry is further configured to cause the memory system to:
generate the address information in accordance with an address of the failed die and a granularity associated with second data stored to the failed die, wherein the address information comprises a plurality of tag bits that indicate a memory die address, a bank group address, a bank address, a subchannel address, a row address, a rank, and a column address associated with a respective data chunk of the second data in accordance with the granularity being a data chunk granularity, and wherein a data chunk comprises a portion of data within a portion of a row of the one or more dies.

10. The memory system of claim 1, wherein the processing circuitry is further configured to cause the memory system to:
determine, in accordance with an error correction and detection operation, that the first die comprises at least a threshold quantity of errors; and
store, in a memory of the controller, the address information that identifies the first die is the failed die in accordance with detecting the threshold quantity of errors in the first die, wherein the address information is stored as a plurality of tag bits that represent a corresponding address of the first die.

11. The memory system of claim 1, wherein the controller comprises an application-specific integrated circuit associated with a compute express link communication protocol.

12. A memory system, comprising:
one or more memory devices; and
processing circuitry coupled with the one or more memory devices and configured to cause the memory system to:
receive an access command for data stored within a first row of the memory system, wherein the access command comprises a first address of the data;
remap, in accordance with the access command, the first address of the data to a second address associated with a second row of the memory system that is different from the first row, wherein remapping the first address to the second address is in accordance with the first address being invalid; and
access, in accordance with the remapping and in response the access command, the data in the second row of the memory system.

13. The memory system of claim 12, wherein, to remap the first address to the second address, the processing circuitry is configured to cause the memory system to:
compare the first address with a plurality of tag addresses stored by the memory system, wherein the plurality of tag addresses indicate invalid addresses within the memory system;
output, in accordance with the comparing, an invalidity indication that indicates the first address is invalid; and
output, in accordance with the comparing, an identifier of a spare row in the memory system, wherein remapping the first address to the second address is in accordance with the invalidity indication and the identifier of the spare row.

14. The memory system of claim 13, wherein the identifier of the spare row points to the second row and replaces a pointer to the first row in the second address.

15. The memory system of claim 13, wherein, to compare the first address with the plurality of tag addresses, the processing circuitry is configured to cause the memory system to:
compare a bank group, a bank address, and a rank included in the first address with the plurality of tag addresses.

16. The memory system of claim 12, wherein the processing circuitry is further configured to cause the memory system to:
receive one or more write commands indicating second data; and
compress the second data indicated via the one or more write commands according to a compression rate before storing the compressed second data to one or more data rows in the memory system, the one or more data rows different from a plurality of spare rows of the memory system, wherein a quantity of the plurality of spare rows is independent from an available logical space within the memory system.

17. The memory system of claim 16, wherein the plurality of spare rows are different from post package repair resources within the memory system.

18. The memory system of claim 12, wherein the first address and the second address comprise a same column address, a same rank, a same bank address, and different row addresses.

19. A method by a memory system, comprising:
receiving, at a controller of the memory system, a request to write data to one or more addresses within one or more dies of the memory system;
comparing the one or more addresses with address information stored within the controller, wherein the address information indicates a first die, of the one or more dies, that is a failed die; and
determining whether to write the data to a buffer within the controller in accordance with the comparing of the one or more addresses with the address information that indicates the failed die, the buffer associated with memory sparing the failed die.

20. The method of claim 19, further comprising:
writing, in accordance with the one or more addresses being different from the address information, the data to the one or more dies.

21. The method of claim 19, further comprising:
writing, in accordance with the one or more addresses matching the address information, the data to the buffer.

22. A method by a memory system, comprising:
receiving an access command for data stored within a first row of the memory system, wherein the access command comprises a first address of the data;
remapping, in accordance with the access command, the first address of the data to a second address associated with a second row of the memory system that is different from the first row, wherein remapping the first address to the second address is in accordance with the first address being invalid; and
accessing, in accordance with the remapping and in response the access command, the data in the second row of the memory system.

23. The method of claim 22, wherein remapping the first address to the second address comprises:
comparing the first address with a plurality of tag addresses stored by the memory system, wherein the plurality of tag addresses indicate invalid addresses within the memory system;
outputting, in accordance with the comparing, an invalidity indication that indicates the first address is invalid; and
outputting, in accordance with the comparing, an identifier of a spare row in the memory system, wherein remapping the first address to the second address is in accordance with the invalidity indication and the identifier of the spare row.

24. An apparatus, comprising:
one or more dies configured to store data;
a first controller coupled with the one or more dies and configured to access the one or more dies; and
a second controller coupled with the first controller and a host system and configured to interface between the host system and the first controller, wherein the second controller comprises:
a memory configured to store address information that identifies a die of the one or more dies that is a failed die;
a buffer configured to store data associated with the failed die; and
a multiplexer configured to receive the data and select, in accordance with the address information in the memory, whether to write the data to the buffer or to transfer the data to the first controller for storage in the one or more dies.

25. The apparatus of claim 24, wherein the memory further comprises:
circuitry configured to compare one or more addresses associated with an access operation with the address information and output, in accordance with the one or more addresses matching the address information, a die identifier that indicates a die associated with the one or more addresses and a way identifier that indicates a location associated with the one or more addresses in the buffer.

26. The apparatus of claim 24, wherein the second controller further comprises:
a second buffer configured to store second data associated with a second failed die of the one or more dies.

27. The apparatus of claim 24, wherein the second controller further comprises:
a second buffer configured to retrieve the data from the buffer and configured to replace second data read from the one or more dies during a read operation with the data retrieved from the buffer in accordance with the second data being read from the failed die.

28. The apparatus of claim 24, wherein the second controller further comprises:
encoding and decoding circuitry configured to encode the data with parity information before the data is transferred to the first controller or to decode the data and the parity information before the data is transferred to the host system.

29. The apparatus of claim 24, wherein the buffer comprises a static random access memory buffer.
